(19) United States
(12) Patent Application Publication
(10) Pub. No.: US 2017/0269647 A1
(43) Pub. Date: Sep. 21, 2017

(54) HEAT DISSIPATION DEVICE AND ELECTRONIC DEVICE USING THE SAME

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: CHING-JOU CHEN, New Taipei (TW); CHIN-MING CHEN, New Taipei (TW); CHIH-SHENG HSIEH, New Taipei (TW); YI-SHIH HSIEH, New Taipei (TW); FENG DU, Wuhan (CN); CHING-YI SHIH, New Taipei (TW)

(21) Appl. No.: 15/387,668

(22) Filed: Dec. 22, 2016

(30) Foreign Application Priority Data
Mar. 21, 2016 (CN) 201620213120.4

(51) Int. Cl. G06F 1/20; F28F 9/00; H05K 7/20; F28F 9/26

(52) U.S. Cl. CPC G06F 1/20; F28F 9/266; F28F 9/002; H05K 7/20172; H05K 7/2039

(57) ABSTRACT

A heat dissipation device includes a heat sink, a centrifugal fan, and a fixing member. The centrifugal fan is enclosed and attached to a heat sink by a fixing member. Air sucked into the centrifugal fan takes away from the heat sink the accumulated heat from an electrical component of an electronic device.

### FIELD

The subject matter herein generally relates to heat dissipation devices.

### BACKGROUND

In general, air pressure generated by a combination of an axial flow fan and a cooling ventilation is very weak, and such arrangement takes up a large space in a computer case.

### BRIEF DESCRIPTION OF THE DRAWINGS

Implementations of the present technology will now be described, by way of example only, with reference to the attached figures.

FIG. 1 is a block diagram of an embodiment of the present disclosure of an electronic device with a heat dissipation device.

FIG. 2 is an exploded, isometric view of the heat dissipation device of FIG. 1 with a centrifugal fan.

FIG. 3 is a schematic diagram of the centrifugal fan of FIG. 2.

FIG. 4 is an assembled, isometric view of the heat dissipation device of FIG. 1.

FIG. 5 is similar to FIG. 4, but viewed from another angle.

FIG. 6 is a cross sectional view of the heat dissipation device of FIG. 4, taken along a line VI-VI.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series, and the like.

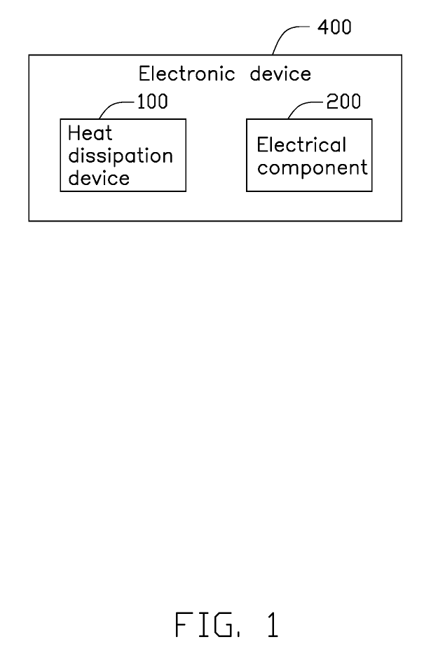

FIG. 1 illustrates an electronic device 400.

The electronic device 400 in an exemplary embodiment comprises a heat dissipation device 100 and an electrical component 200. The heat dissipation device 100 is configured to dissipate heat generated by the electrical component 200. In at least one embodiment, the electronic device 400 can be a computer.

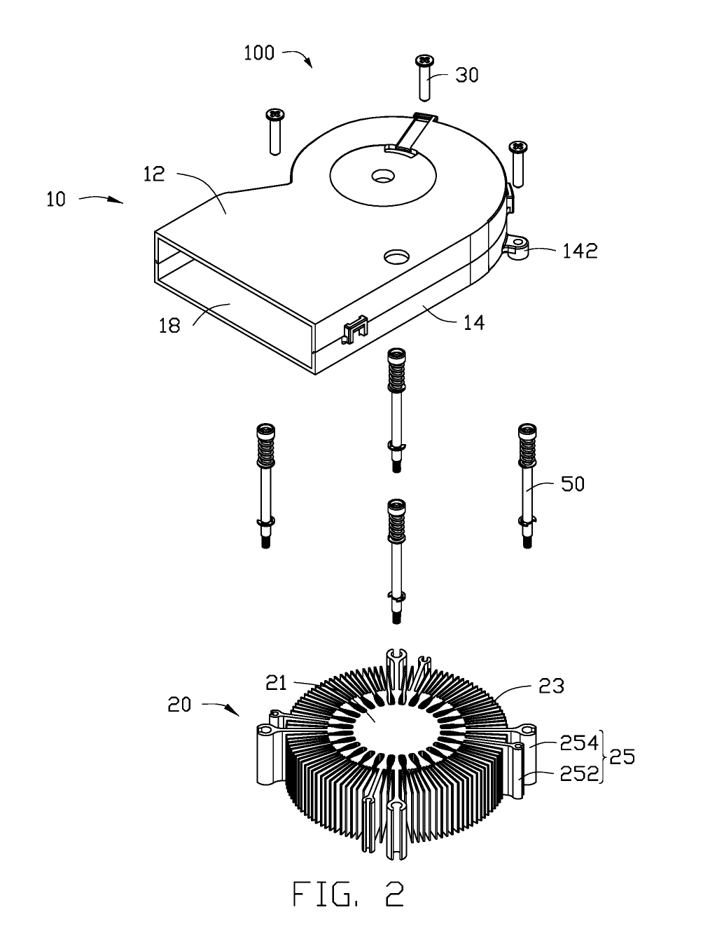

FIG. 2 illustrates that the heat dissipation device 100 comprises a centrifugal fan 10 and a heat sink 20.

The heat sink 20 comprises a cylindrical thermal conductor 21 and a fins group 23, in a circular overall shape. The fins group 23 comprises a plurality of fins. The fins group 23 extends around the cylindrical thermal conductor 21.

Four mounting suites 25 are defined in the fins group 23. The four mounting suites 25 are distributed at the four corners of a rectangle.

Each mounting suite 25 comprises a mounting sleeve 252 and a mounting groove 254. Four mounting sleeves 252 and four mounting grooves 254 are extended from the fins group 23 along a horizontal direction.

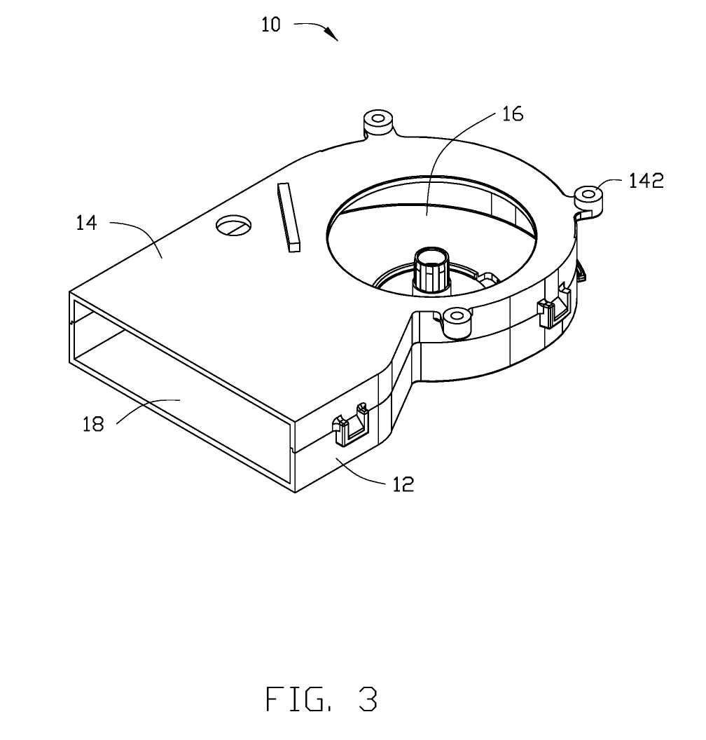

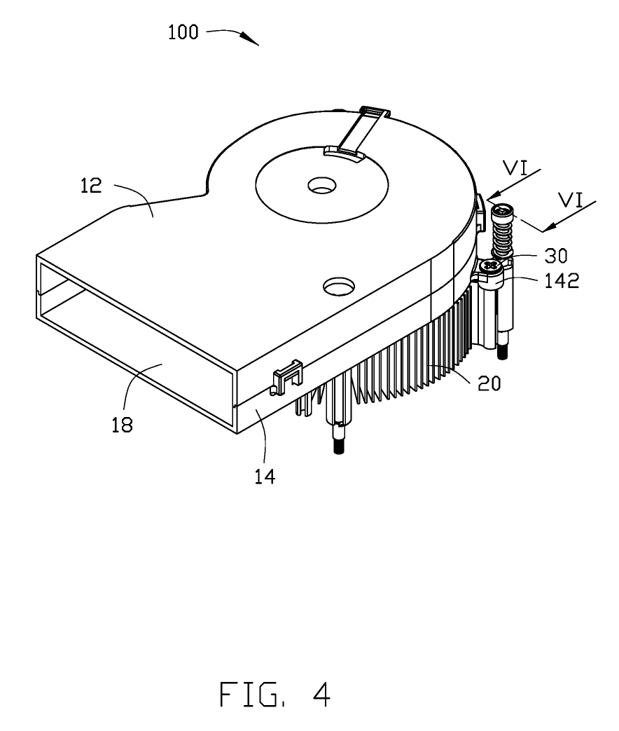

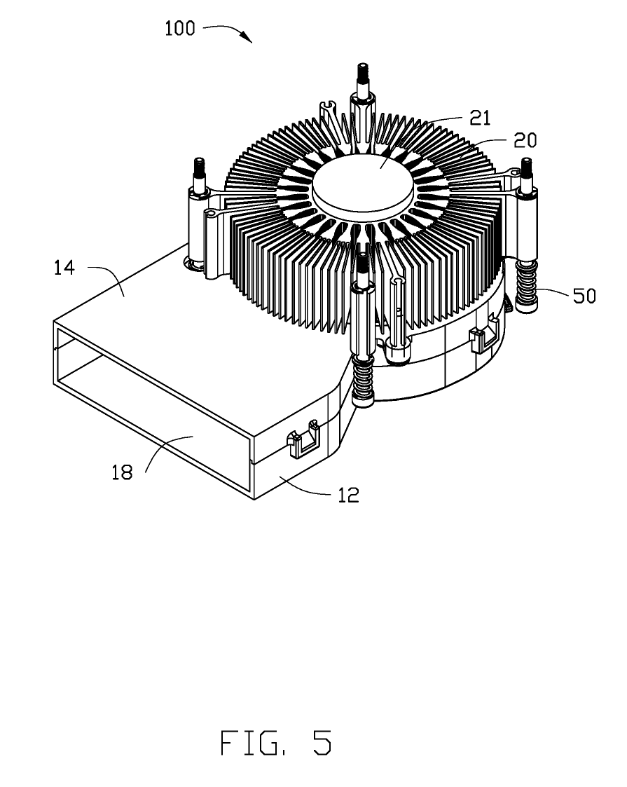

FIGS. 3-5 illustrate that the centrifugal fan 10 comprises an upper cover 12, a bottom cover 14, and a fan impeller (not shown in figures). The upper cover 12 and the bottom cover 14 together forms an enclosed space, and the fan impeller occupies the enclosed space.

A suction outlet 16 is defined in the bottom cover 14 for drawing in local air (that is to say, air within the electronic device 400) into the enclosed space when the fan impeller is energized. An exhaust outlet 18 is defined in the enclosed space to discharge air sucked from the suction outlet 16.

The bottom cover 14 has three flanges 142 extending horizontally outward, and the three flanges 142 correspond to the positions of any three mounting sleeves 252 of the heat sink 20.

A fixing member 30 is aligned with the flange 142, and the fixing member 30 is perpendicularly mounted to the flange 142. The fixing member 30 extends through the flange 142 and is engaged in the mounting sleeves 252 of the bottom cover 14, to fix the centrifugal fan 10 with the heat sink 20. In at least one embodiment, the fixing member 30 can be a screw.

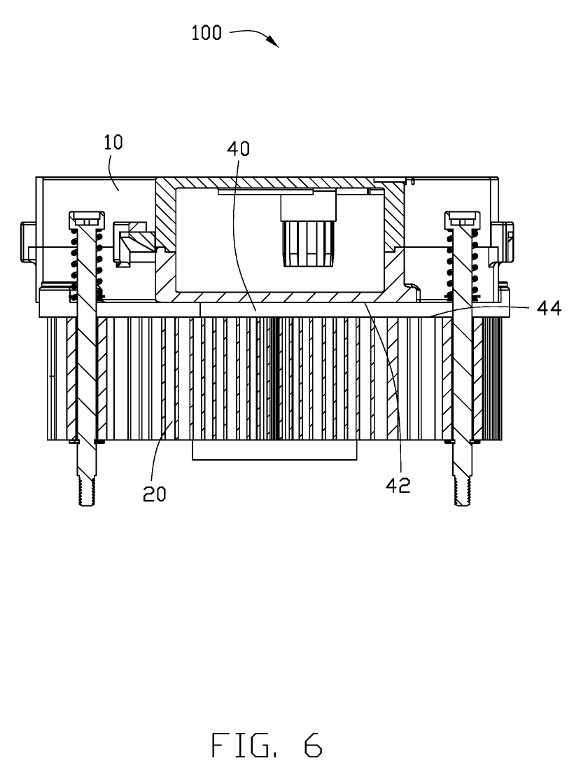

FIG. 6 illustrates that a gap 40 is formed between a first surface 42 in which the bottom cover 14 is located and a second surface 44 where a top of the fins group 23 is located, to increase the air intake area.

The reduced air pressure leads to a corresponding increase in air flow rate between the centrifugal fan 10 and the heat sink 20, and the heat removal efficiency can be improved.

When it is desired to mount the heat dissipation device 100 in the electronic device 400, it is only necessary that four positioning parts 50 respectively extend through four mounting grooves 254 to engage in four mounting holes of a circuit board on which the electrical component 200 is located. At this time, the cylindrical thermal conductor 21 of the heat sink 20 will be directed to one electrical component 200, and the heat generated by the electrical component 200 is conducted to the cylindrical thermal conductor 21.

For example, when the electrical component 200 is a central processing unit (CPU), the cylindrical thermal conductor 21 of the heat sink 20 is directed to the CPU, and the cylindrical thermal conductor 21 takes heat from the CPU. Due to rotation of the centrifugal fan 10, air pressure increases an amount of air drawn in by the suction outlet 16 of the centrifugal fan 10, and heat can be simultaneously removed from other heating elements (such as a hard disk) in the electronic device 400.

In operation, the components of the electronic device 400 give off heat. The heat generated by the electrical components 200 or one of them is conducted to the fins group 23 through the cylindrical thermal conductor 21. At this time, the centrifugal fan 10 generates enough reduction in air pressure to suck cold air in the system from the suction outlet 16. The centrifugal fan 10 removes heat from other heating elements in the electronic device 400, and hot air is discharged through the exhaust outlet 18. Thus, the cooling air sucked by the centrifugal fan 10 dissipates heat from the fins group 23, thereby lowering the temperatures of the plurality of electrical component 200.

The embodiments shown and described above are only examples. Many details are often found in the art such as the other features of electronic device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A heat dissipation device configured for dissipating heat generated by an electrical component of an electronic device, comprising:
a heat sink;
a centrifugal fan comprising a bottom cover, the bottom cover defining a suction outlet; and
a fixing member configured for fixing the centrifugal fan with the heat sink;
wherein air sucked into the suction outlet of the centrifugal fan takes away the heat of the electrical component and dissipates heat for the electronic device.

2. The heat dissipation device of claim 1, wherein the heat sink comprises a cylindrical thermal conductor and a fins group, the fins group defines a mounting suite, the bottom cover of the centrifugal fan defines a flange, and the fixing member extends through the flange and is engaged in the mounting suite of the bottom cover, to fix the centrifugal fan with the heat sink.

3. The heat dissipation device of claim 2, wherein the mounting suite comprises a mounting sleeve, the fixing member extends through the flange and is engaged in the mounting sleeve of the bottom cover, to fix the centrifugal fan with the heat sink together.

4. The heat dissipation device of claim 3, wherein a gap is defined between a first surface in which the bottom cover is located and a second surface where a top of the fins group is located, to increase the air intake area.

5. The heat dissipation device of claim 1, wherein the fixing member is a screw.

6. A heat dissipation device configured for dissipating heat generated by an electrical component of an electronic device, comprising:
a heat sink comprises a cylindrical thermal conductor and a fins group, wherein the fins group defines a mounting suite;
a centrifugal fan comprising a bottom cover, the bottom cover defining a suction outlet and a flange; and
a fixing member extends through the flange and is engaged in the mounting suite of the bottom cover, to fix the centrifugal fan with the heat sink;
wherein air sucked into the suction outlet of the centrifugal fan takes away the heat of the electrical component and dissipates heat for the electronic device.

7. The heat dissipation device of claim 6, wherein the mounting suite comprises a mounting sleeve, the fixing member extends through the flange and is engaged in the mounting sleeve of the bottom cover, to fix the centrifugal fan with the heat sink together.

8. The heat dissipation device of claim 7, wherein a gap is defined between a first surface in which the bottom cover is located and a second surface where a top of the fins group is located, to increase the air intake area.

9. The heat dissipation device of claim 6, wherein the fixing member is a screw.

10. An electronic device comprising a heat dissipation device and an electrical component, the heat dissipation device configured for dissipating heat generated by the electrical component, the heat dissipation device comprising:
a heat sink;
a centrifugal fan comprising a bottom cover, the bottom cover defining a suction outlet; and
a fixing member configured for fixing the centrifugal fan with the heat sink;
wherein air sucked into the suction outlet of the centrifugal fan takes away the heat of the electrical component and dissipates heat for the electronic device.

11. The electronic device of claim 10, wherein the heat sink comprises a cylindrical thermal conductor and a fins group, the fins group defines a mounting suite, the bottom cover of the centrifugal fan defines a flange, and the fixing member extends through the flange and is engaged in the mounting suite of the bottom cover, to fix the centrifugal fan with the heat sink.

12. The electronic device of claim 11, wherein the mounting suite comprises a mounting sleeve, the fixing member extends through the flange and is engaged in the mounting sleeve of the bottom cover, to fix the centrifugal fan with the heat sink together.

13. The electronic device of claim 12, wherein a gap is defined between a first surface in which the bottom cover is located and a second surface where a top of the fins group is located, to increase the air intake area.

14. The electronic device of claim 10, wherein the fixing member is a screw.

15. The electronic device of claim 10, wherein the electronic device is a computer.
